(19) United States
(12) Patent Application Publication
(10) Pub. No.: US 2026/0068741 A1
(43) Pub. Date: Mar. 5, 2026

(54) SEMICONDUCTOR PACKAGE

(71) Applicant: Samsung Electronics Co., Ltd., Suwon-si (KR)

(72) Inventors: Dongkuk LEE, Suwon-si (KR); Seungduk BAEK, Suwon-si (KR); Sunkyoung SEO, Suwon-si (KR); Chajea JO, Suwon-si (KR)

(73) Assignee: Samsung Electronics Co., Ltd., Suwon-si (KR)

(21) Appl. No.: 19/308,949

(22) Filed: Aug. 25, 2025

(30) Foreign Application Priority Data
Aug. 29, 2024 (KR) 10-2024-0116942

(51) Int. Cl. H01L 23/31; H01L 23/00; H01L 23/48; H01L 25/04

(52) U.S. Cl. CPC H01L 23/3185

(57) ABSTRACT

Provided is a semiconductor package including a package substrate, a pair of first semiconductor chips on the package substrate and facing each other in a horizontal direction, a pair of second semiconductor chips on the pair of first semiconductor chips and facing each other in the horizontal direction, and a pair of molding members covering a periphery of the pair of second semiconductor chips on the pair of first semiconductor chip and a part of the pair of molding members on the package substrate, each of the pair of molding members include first and second widths in the horizontal direction, the first width in a first region where the pair of second semiconductor chips face each other is less than the second width in a second region where the pair of second semiconductor chips do not face each other.

### CROSS-REFERENCE TO RELATED APPLICATION

This application is based on and claims priority under 35 U.S. C. § 119 to Korean Patent Application No. 10-2024-0116942, filed on Aug. 29, 2024, in the Korean Intellectual Property Office, the disclosure of which is incorporated by reference herein in its entirety.

### BACKGROUND

The inventive concepts relate to semiconductor packages, and more particularly, to semiconductor packages for improved mounting of semiconductor chips in a limited structure of a semiconductor package.

As the demand for mobile devices has rapidly increased in the electronic product market, miniaturization and lightweighting of electronic parts mounted on such products have also been continuously desired. To implement the miniaturization and lightweighting of electronic parts, technologies to reduce the size of individual mounting parts are desired along with the semiconductor packaging technologies for integrating multiple individual devices into one package. In particular, as semiconductors having high performance and high capacity are desired, the number of semiconductor chips mounted on a semiconductor package increases. However, due to the spatial constraint of semiconductor packages, technologies to overcome such spatial limitation by changing an arrangement of semiconductor chips have been demanded.

### SUMMARY

The inventive concepts provide semiconductor packages capable of improving the reliability of semiconductor chips mounted on the semiconductor package and/or reducing a connection distance of wires for signal connection among the semiconductor chips.

The technical tasks which the technical ideas of the inventive concepts seek to solve is not limited to the above-mentioned tasks, and other tasks that have not been mentioned may also be clearly understood by a person skilled in the art from the following descriptions.

According to some aspects of the inventive concepts, there is provided a semiconductor package including a package substrate, a pair of first semiconductor chips on the package substrate and facing each other in a horizontal direction, a pair of second semiconductor chips on the pair of first semiconductor chips and facing each other in the horizontal direction, a pair of molding members covering a periphery of the pair of second semiconductor chips on the pair of first semiconductor chip, and an encapsulation covering a periphery of the pair of first semiconductor chips and a part of the pair of molding members on the package substrate, each of the pair of molding members include first and second widths in the horizontal direction, the first width in a first region where the pair of second semiconductor chips face each other is less than the second width in a second region where the pair of second semiconductor chips do not face each other, and a first upper surface of the encapsulation in the first region is higher than a second upper surface of the encapsulation in the second region.

According to some aspects of the inventive concepts, there is provided a semiconductor package including a package substrate, a pair of first semiconductor chips on the package substrate and facing each other in a horizontal direction, a pair of second semiconductor chips on the pair of first semiconductor chips and facing each other in the horizontal direction, a pair of molding members covering a periphery of the pair of first semiconductor chips, and an encapsulation covering a periphery of the pair of molding members and a part of the pair of second semiconductor chips on the package substrate, each of the pair of molding members include first and second widths in the horizontal direction, the first width in a first region where the pair of first semiconductor chips face each other is less than the second width in a second region where the pair of first semiconductor chips do not face each other, and, a first upper surface of the encapsulation in the first region is higher than a second upper surface of the encapsulation in the second region.

According to some aspects of the inventive concepts, there is provided a semiconductor package including a package substrate, a plurality of first semiconductor chips on the package substrate and facing each other in a horizontal direction, a plurality of second semiconductor chips on the plurality of first semiconductor chips and facing each other in the horizontal direction, a plurality of third semiconductor chips on the plurality of second semiconductor chips and facing each other in the horizontal direction, a plurality of molding members covering peripheries of the plurality of second semiconductor chips and the plurality of third semiconductor chips on the plurality of first semiconductor chips, and an encapsulation covering a periphery of the plurality of first semiconductor chips and a part of the plurality of molding members on the package substrate, each of the plurality of molding members include first and second widths in the horizontal direction, the first width in a first region where the plurality of second semiconductor chips face each other is less than the second width in a second region where the plurality of second semiconductor chips do not face each other, and a first upper surface of the encapsulation in the first region is higher than a second upper surface of the encapsulation in the second region.

### BRIEF DESCRIPTION OF THE DRAWINGS

Example embodiments will be more clearly understood from the following detailed description taken in conjunction with the accompanying drawings in which:

FIG. 1 is a cross-sectional view illustrating major components of a semiconductor package according to some example embodiments;

FIGS. 2 to 9 are cross-sectional views illustrating by step a method of manufacturing a semiconductor package according to some example embodiments;

FIGS. 10 to 14 are cross-sectional views illustrating major components of a semiconductor package according to some example embodiments;

FIGS. 15 to 19 are plan views illustrating major components of a semiconductor package according to some example embodiments; and

FIG. 20 is a block diagram schematically illustrating configuration of a semiconductor package according to some example embodiments.

### DETAILED DESCRIPTION OF THE EMBODIMENTS

Hereinafter, example embodiments of the technical ideas of the inventive concepts will be described in detail with reference to the accompanying drawings.

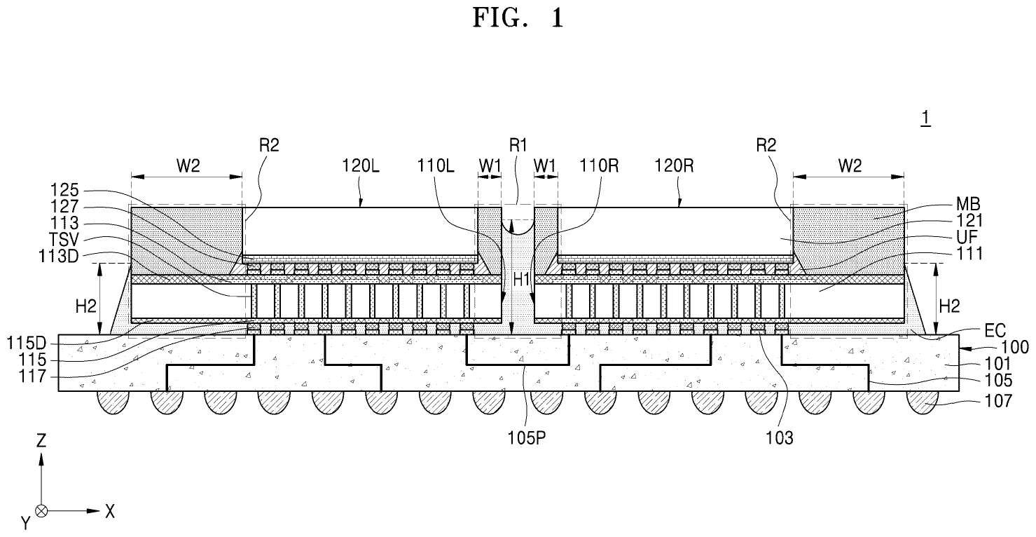

FIG. 1 is a cross-sectional view illustrating major components of a semiconductor package according to some example embodiments.

Referring to FIG. 1, a semiconductor package 1 may include a package substrate 100, a pair of first semiconductor chips 110R and 110L, a pair of second semiconductor chips 120R and 120L, an underfill UF, a molding member MB, and an encapsulation EC.

In a system-in package which is a system in which a plurality of individual semiconductor chips are integrated into one package, the number of semiconductor packages constituting the semiconductor package 1 may vary according to the use of the semiconductor package 1. That is, although the drawings illustrate that four semiconductor chips are mounted on the package substrate 100, the number of semiconductor chips constituting the semiconductor package 1 is not limited to the numbers shown in the drawings.

For convenience, semiconductor chips of the same type are described collectively. That is, the presence of the first semiconductor chip and the second semiconductor chip indicates that there are two types of semiconductor chips.

That package substrate 100 may include as a support substrate a body portion 101, a lower protection layer (not shown), and an upper protection layer (not shown). The package substrate 100 may include a printed circuit board (PCB), a wafer substrate a ceramic substrate, a glass substrate, etc. In some example embodiments, the package substrate 100 may be a printed circuit board.

In the printed circuit board the body portion 101 may generally be implemented by forming a thin film by compressing a high molecular substance such as material thermosetting resin, etc., epoxy resin such as Flame Retardant 4 (FR-4), Bismaleimide Triazine (BT), Ajinomoto Build up Film (ABF), etc., or phenol resin, etc. into a certain thickness, covering both surfaces thereof with copper foil, and forming wires, which are transmission pathways for electrical signal, through patterning.

The package substrate 100 may include a lower electrode pad (not shown) and an upper electrode pad 103. In addition, a wiring layer 105 may be formed in the package substrate 100, and the wiring layer 105 may be electrically connected to the first semiconductor chips 110R and 110L and the second semiconductor chips 120R and 120L connected to the upper electrode pad 103 on the upper surface of the package substrate 100.

An external connection terminal 107 may be arranged on the lower electrode pad on the lower surface of the package substrate 100. The package substrate 100 may be electrically connected and mounted on a module substrate (not shown) or a system board (not shown) of an electronic product through the external connection terminal 107.

The pair of first semiconductor chips 110R and 110L may be mounted on the package substrate 100. The pair of first semiconductor chips 110R and 110L may respectively be referred to as a left first semiconductor chip 110L and a right first semiconductor chip 110R according to their positions in the drawings.

In some example embodiments, the pair of first semiconductor chips 110R and 110L may further include a circuit region (not shown) and a buffer circuit capable of capacitance loading may be formed in the circuit region. In some example embodiments, the circuit region may include at least one selected from a transistor, a diode, a capacitor, and/or a resistor. In some example embodiments, each of the pair of first semiconductor chips 110R and 110L may be an interposer.

Each of the pair of first semiconductor chips 110R and 110L may include a base substrate 111, an upper redistribution layer 113 formed on an upper surface of the base substrate 111, and a lower redistribution layer 115 formed on a lower surface of the base substrate 111. An upper insulating layer 113D may be arranged around the upper redistribution layer 113, and a lower insulating layer 115D may be arranged around the lower redistribution layer 115.

The base substrate 111 may be a wafer including silicon (Si), for example, crystalline silicon, polycrystalline silicon, or amorphous silicon. Each of the pair of first semiconductor chips 110R and 110L may include a plurality of through silicon vias TSV passing through the base substrate 111.

In some example embodiments, the plurality of through silicon vias TSV may be arranged only in a region where the left first semiconductor chip 110L and the left second semiconductor chip 120L overlap each other in a vertical direction (Z direction) and a region where the right first semiconductor chip 110R and the right second semiconductor chip 120R overlap each other in the vertical direction (Z direction).

The pair of first semiconductor chips 110R and 110L may be electrically connected to the package substrate 100 through a first internal connection terminal 117 located under the lower redistribution layer 115. In addition, a connection wiring layer 105P may be formed in the package substrate 100, and the connection wiring layer 105P may provide electrical connection between the pair of first semiconductor chips 110R and 110L.

The pair of second semiconductor chips 120R and 120L may be mounted on the pair of first semiconductor chips 110R and 110L. The pair of second semiconductor chips 120R and 120L may respectively be referred to as the left second semiconductor chip 120L and the right second semiconductor chip 120R according to their positions in the drawings. That is, the left second semiconductor chip 120L may be mounted on the left first semiconductor chip 110L, and the right second semiconductor chip 120R may be mounted on the right first semiconductor chip 110R.

In some example embodiments, each of the pair of second semiconductor chips 120R and 120L may be a memory chip, and may include, for example, a volatile memory chip and/or a non-volatile memory chip. The pair of second semiconductor chips 120R and 120L may include a memory chip set capable of mutual data aggregation. In some example embodiments, each of the pair of second semiconductor chips 120R and 120L may be a logic device, for example, a central processing unit chip, a graphic processing unit chip, or an application processor chip. That is, the pair of second semiconductor chips 120R and 120L and the pair of first semiconductor chips 110R and 110L may have different functions from each other.

In some example embodiments, a width of each of the pair of second semiconductor chips 120R and 120L in a first horizontal direction (X direction) may be less than a width of each of the pair of first semiconductor chips 110R and 110L in the first horizontal direction (X direction).

Each of the pair of second semiconductor chips 120R and 120L may include a base substrate 121 and a lower wiring layer 125 formed on a lower surface of the base substrate 121. The base substrate 121 may be a wafer including silicon (Si), for example, crystalline silicon, polycrystalline silicon, or amorphous silicon.

The pair of second semiconductor chips 120R and 120L may be electrically connected to the pair of first semiconductor chips 110R and 110L through a second internal connection terminal 127 (or bumps) located under the lower wiring layer 125.

The underfill UF may be formed in a space between the left first semiconductor chip 110L and the left second semiconductor chip 120L and a space between the right first semiconductor chip 110R and the right second semiconductor chip 120R. That is, in the process of electrical connection of the second internal connection terminal 127, a gap may be formed between the pair of first semiconductor chips 110R and 110L and the pair of second semiconductor chips 120R and 120L. As such gap may cause an issue of connection reliability of the pair of first semiconductor chips 110R and 110L and the pair of second semiconductor chips 120R and 120L, the underfill UF may be formed to reinforce the connection.

The molding member MB may be formed to surround a lateral surface of each of the pair of second semiconductor chips 120R and 120L. However, unlike the description of drawings, the upper surfaces of the pair of second semiconductor chips 120R and 120L may be covered by the molding member MB. The molding member MB may protect the pair of second semiconductor chips 120R and 120L from external influences such as contamination (e.g., moisture or gas), impacts, etc.

The molding member MB may include, for example, an epoxy molding compound. The epoxy molding compound may have a Young's modulus of about or exactly 15 GPa to about or exactly 30 GPa and a coefficient of thermal expansion of about or exactly 3 ppm to about or exactly 30 ppm. The material of the molding member MB is not limited to the epoxy molding compound, and may include, for example, an epoxy material, a thermosetting material, a thermoplastic material, an UV-processed material, etc. The thermosetting material may include a phenol-type hardener, an acid anhydride-type hardener, an amine-type hardener, and/or an acryl polymer additive.

The encapsulation EC may be formed to cover the periphery of the pair of first semiconductor chips 110R and 110L and a part of the molding member MB surrounding the pair of second semiconductor chips 120R and 120L, on the package substrate 100.

The encapsulation EC may include a material identical, substantially identical, or similar to the material of the molding member MB. That is, the encapsulation EC may include an epoxy molding compound; however, the inventive concepts are not limited thereto.

The semiconductor package 1 according to the inventive concepts may include the molding member MB having an asymmetrical shape (e.g., an asymmetrical overhang) on both sidewalls of each of the pair of second semiconductor chips 120R and 120L.

In this regard, a region located between the facing second semiconductor chips 120R and 120L is referred to as a first region R1, and a region located where the second semiconductor chips 120R and 120L do not face each other is referred to as a second region R2.

That is, with respect to the left second semiconductor chip 120L, the width of the molding member MB in the first horizontal direction (X direction) may be a first width W1 in the first region R1 and a second width W2, which is greater than the first width W1, in the second region R2. In addition, with respect to the right second semiconductor chip 120R, the width of the molding member MB in the first horizontal direction (X direction) may be the first width W1 in the first region R1 and the second width W2, which is greater than the first width W1, in the second region R2.

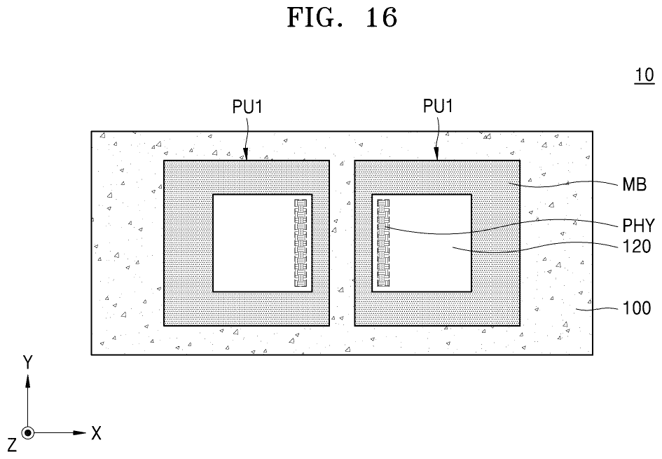

By forming the first width W1 of the molding member MB in the first horizontal direction (X direction) in the first region R1 relatively shorter than the second width W2, the physical distance between the left second semiconductor chip 120L and the right second semiconductor chip 120R may be designed to be closer. This may reduce the distance between the pair of physical signal connection structures PHY (see FIG. 16) configured to receive and transmit signals between the left second semiconductor chip 120L and the right second semiconductor chip 120R, thereby decreasing the connection distance of wires for signal connection. In this regard, the pair of physical signal connection structures PHY (see FIG. 16) included in the pair of second semiconductor chips 120R and 120L may be electrically connected to each other through the pair of first semiconductor chips 110R and 110L and the package substrate 100.

In addition, by forming the second width W2 of the molding member MB in the first horizontal direction (X direction) in the second region R2 relatively longer than the first width W1, the reliability in protection of left second semiconductor chip 120L and the right second semiconductor chip 120R from external influences may be improved.

Furthermore, the reliability in protection of a part of the molding member MB, which has a relatively smaller width in the first region R1 (compared to, e.g., the pair of semiconductor chips 110R and 110L being placed equidistant from one another and an edge of the semiconductor package 1), may be reinforced by the encapsulation EC. That is, as for the height of the encapsulation EC, a first height H1 in the first region R1 may be greater than a second height H2 in the second region R2. In other words, in regard to a vertical level of an uppermost surface of the encapsulation EC, a first level in the first region R1 may be higher than a second level in the second region R2.

In some example embodiments, a sidewall of each of the pair of first semiconductor chips 110R and 110L may be coplanar with a sidewall of each of the molding members MB in the vertical direction (Z direction), and the encapsulation EC may have a round upper surface in the first region R1 and an inclined sidewall in the second region R2.

In some example embodiments, a vertical level of the uppermost surface of the molding member MB may be identical or substantially identical to a vertical level of an uppermost surface of the second semiconductor chips 120R and 120L, and the vertical level of the uppermost surface of the molding member MB may be arranged higher than a vertical level of an uppermost surface of the encapsulation EC.

Ultimately, the semiconductor package 1 according to the inventive concepts may reduce a connection distance of wires for signal connection between the pair of first semiconductor chips 110R and 110L while maintaining the reliability in protection of the pair of first semiconductor chips 110R and 110L and the pair of second semiconductor chips 120R and 120L mounted on the package substrate 100.

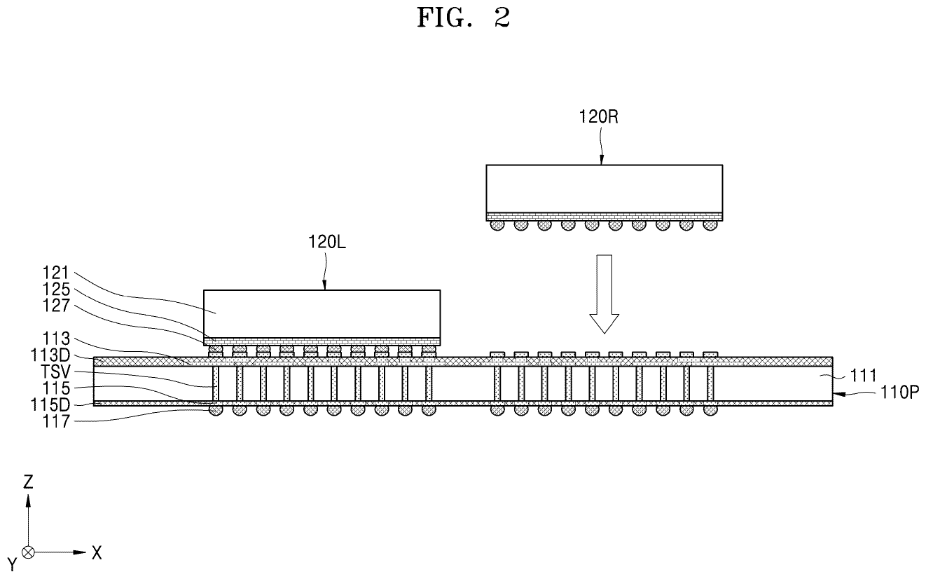

FIGS. 2 to 9 are cross-sectional views illustrating by step a method of manufacturing a semiconductor package according to some example embodiments.

Referring to FIG. 2, the left second semiconductor chip 120L may be mounted on a first semiconductor panel 110P.

The first semiconductor panel 110P may be prepared. The first semiconductor panel 110P may include the base substrate 111, the upper redistribution layer 113 formed on the upper surface of the base substrate 111, and the lower redistribution layer 115 formed on the lower surface of the base substrate 111. The upper insulating layer 113D may be arranged around the upper redistribution layer 113, and the lower insulating layer 115D may be arranged around the lower redistribution layer 115. The first semiconductor panel 110P may include the first internal connection terminal 117 under the lower redistribution layer 115.

First, the left second semiconductor chip 120L may be mounted on the first semiconductor panel 110P. The left second semiconductor chip 120L may be mounted close to the central portion of the first semiconductor panel 110P. For example, a central position of the left second semiconductor chip 120L may be offset from a central position of the first semiconductor panel 110P.

Then, the right second semiconductor chip 120R may be located on the first semiconductor panel 110P. The right second semiconductor chip 120R may be located close to the central portion of the first semiconductor panel 110P. For example, a central position of the right second semiconductor chip 120R may be offset from a central position of the first semiconductor panel 110P.

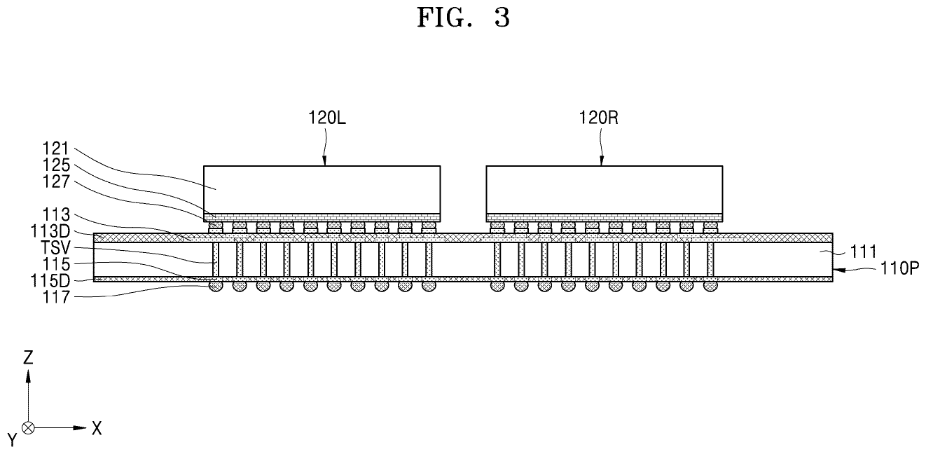

Referring to FIG. 3, the right second semiconductor chip 120R may be mounted on the first semiconductor panel 110P.

The right second semiconductor chip 120R may be mounted close to the central portion of the first semiconductor panel 110P. For example, a central position of the right second semiconductor chip 120L may be offset from a central position of the first semiconductor panel 110P. The first semiconductor panel 110P may be electrically and physically connected to the pair of second semiconductor chips 120R and 120L through the second internal connection terminal 127.

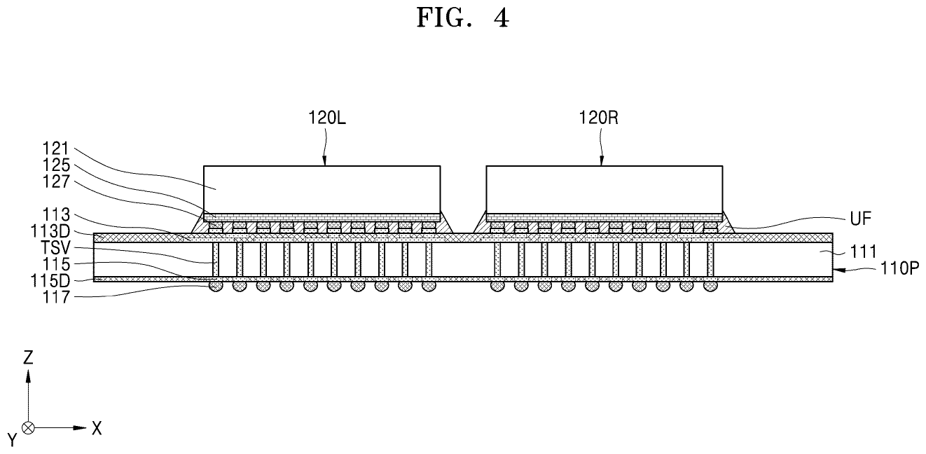

Referring to FIG. 4, the underfill UF may be injected between the first semiconductor panel 110P and each of the pair of second semiconductor chips 120R and 120L.

The underfill UF may be injected into a region between the first semiconductor panel 110P and the left second semiconductor chip 120L and a region between the first semiconductor panel 110P and the right second semiconductor chip 120R. That is, in the process of electrical connection of the second internal connection terminal 127, the underfill UF may be injected between the first semiconductor panel 110P and the pair of second semiconductor chips 120R and 120L to reinforce the connection.

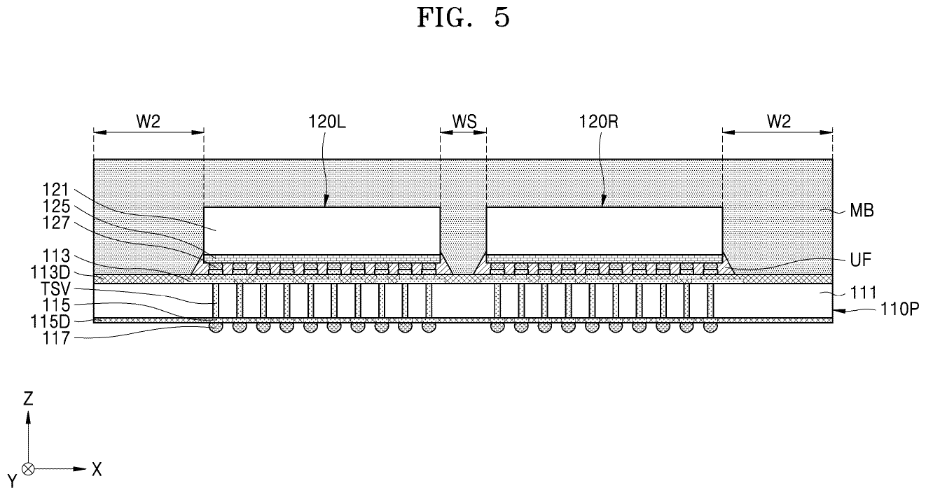

Referring to FIG. 5, on the first semiconductor panel 110P, the molding member MB may be formed to surround the underfill UF and the pair of second semiconductor chips 120R and 120L.

According to the inventive concepts, the molding member MB having an asymmetrical shape (e.g., an asymmetrical overhang) may be formed on both sidewalls of each of the pair of second semiconductor chips 120R and 120L.

That is, the molding member MB may be formed to have an in-between width WS in the region between the pair of second semiconductor chips 120R and 120L and have the second width W2, which is greater than the in-between width WS in an outer region of the pair of second semiconductor chips 120R and 120L.

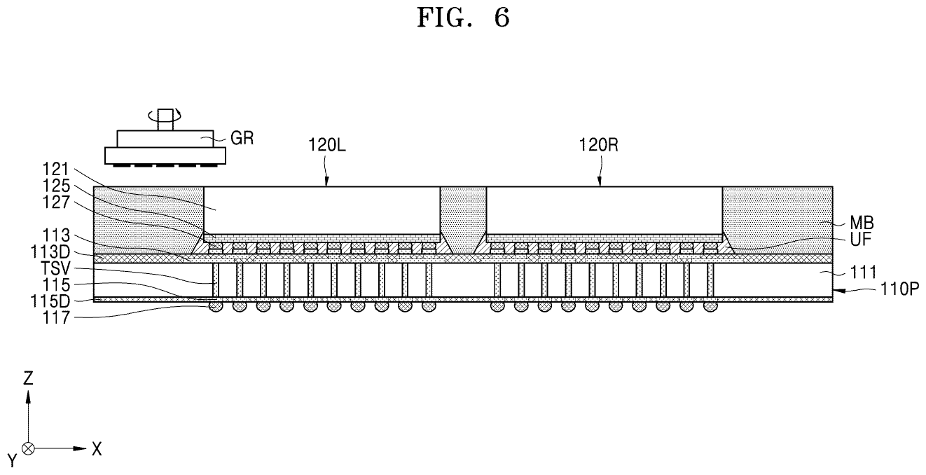

Referring to FIG. 6, by partially removing the molding member MB, the upper surface of the pair of second semiconductor chips 120R and 120L may be exposed.

By using a grinder GR, the polishing and planarization process may be performed on the molding member MB. The polishing and planarization process may be a chemical and/or mechanical polishing process. The grinder GR may partially remove the molding member MB to form a flat surface including the exposed upper surfaces of the second semiconductor chips 120R and 120L. In some example embodiments, upper surfaces of the molding member MB and upper surfaces of the second semiconductor chips 120R and 120L may be coplanar or substantially coplanar.

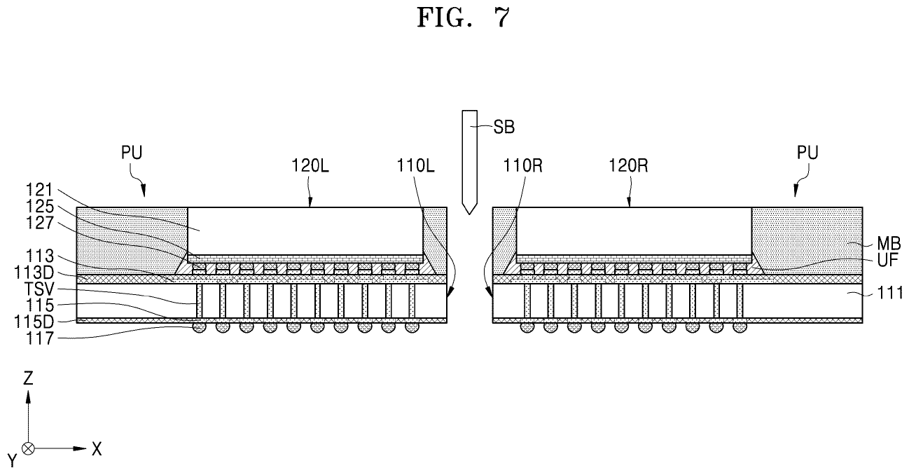

Referring to FIG. 7, by using a sawing blade SB, the molding member MB and the first semiconductor panel 110P (see FIG. 6) may be cut into separate package units PU.

Accordingly, the package unit PU may be physically separated from each other while the pair of second semiconductor chips 120R and 120L are respectively mounted on the pair of first semiconductor chips 110R and 110L. That is, the left second semiconductor chip 120L may be mounted on the left first semiconductor chip 110L to form a left package unit PU, and the right second semiconductor chip 120R may be mounted on the right first semiconductor chip 110R to form a right package unit PU.

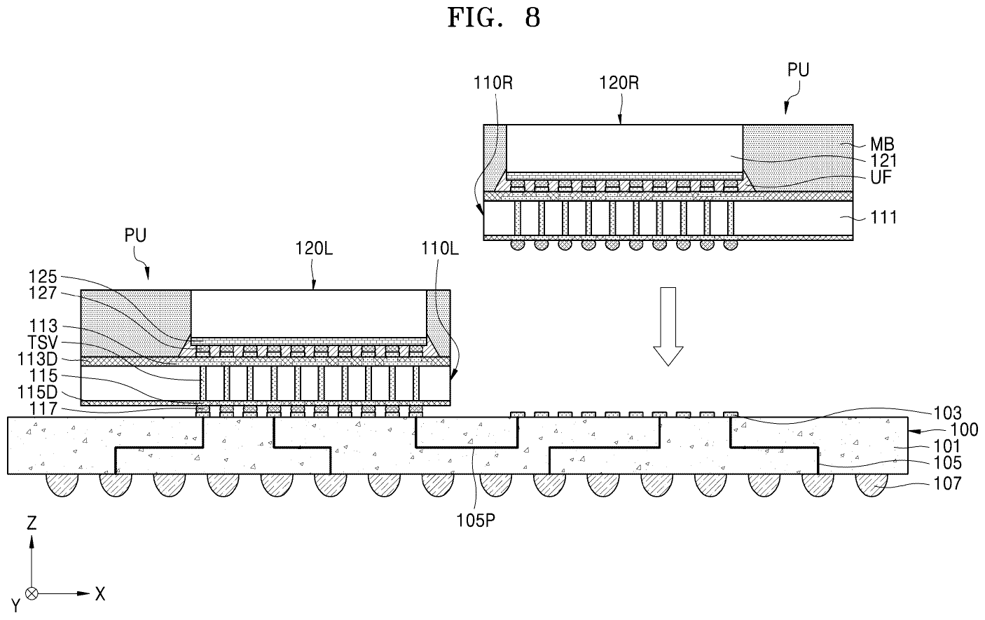

Referring to FIG. 8, the left package unit PU may be mounted on the package substrate 100.

The package substrate 100 may be prepared. The package substrate 100 may include a lower electrode pad (not shown) and the upper electrode pad 103 in the body portion 101. In addition, the package substrate 100 may include the wiring layer 105 in the body portion 101. The external connection terminal 107 may be arranged on the lower electrode pad on the lower surface of the package substrate 100.

First, the left package unit PU may be mounted on the package substrate 100. The left package unit PU may be mounted close to the central portion of the package substrate 100. For example, a central position of the left package unit PU may be offset from a central position of the package substrate 100.

Next, the right package unit PU may be arranged on the package substrate 100. The right package unit PU may be located close to the central portion of the package substrate 100. For example, a central position of the right package unit PU may be offset from a central position of the package substrate 100.

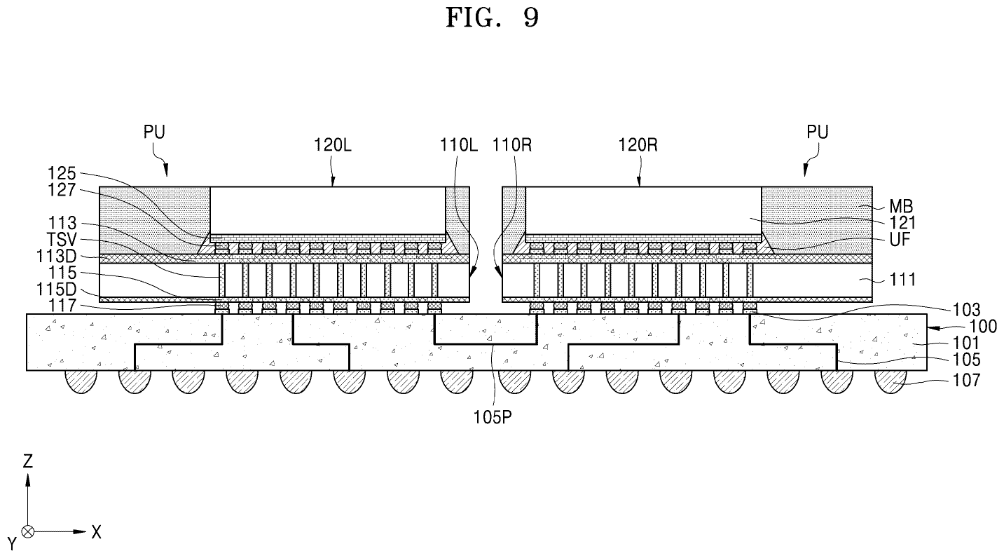

Referring to FIG. 9, the right package unit PU may be mounted on the package substrate 100.

The right package unit PU may be mounted close to the central portion of the package substrate 100. For example, a central position of the right package unit PU may be offset from a central position of the package substrate 100. The package substrate 100 and the pair of package units PU may be electrically and physically connected to each other through the first internal connection terminal 117.

Referring to FIG. 1, the encapsulation EC may be formed to cover the periphery of the pair of first semiconductor chips 110R and 110L and a part of the molding member MB surrounding the pair of second semiconductor chips 120R and 120L, on the package substrate 100.

In this manner, the semiconductor package 1 according to the inventive concepts may be completed.

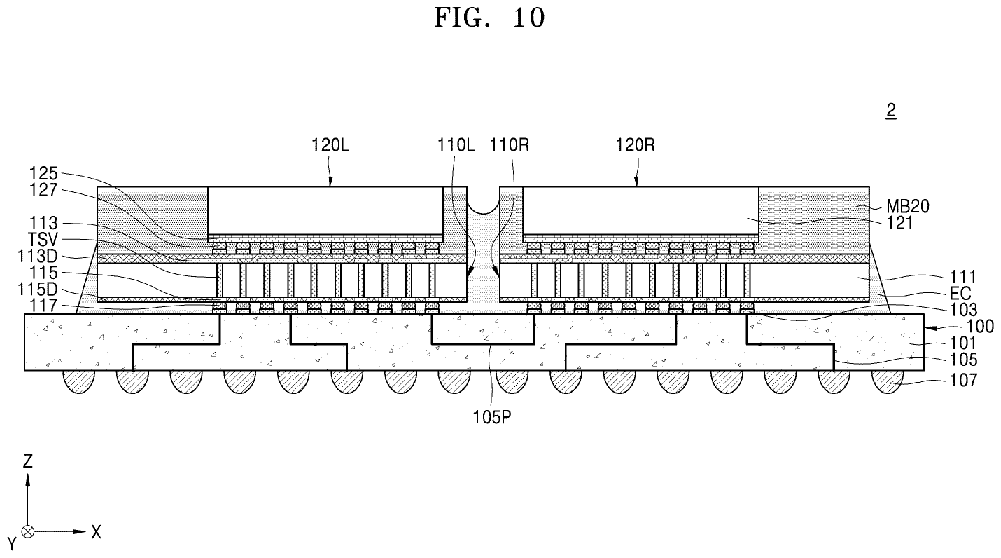

FIGS. 10 to 14 are cross-sectional views illustrating major components of a semiconductor package according to some example embodiments.

Most of the components of the semiconductor packages (2, 3, 4, 5, and 6) and materials constituting the components described below are identical, substantially identical, or similar to those described above with reference to FIG. 1. Accordingly, for convenience in explanation, descriptions thereon will focus on the differences from the semiconductor package 1 described above.

Referring to FIG. 10, a semiconductor package 2 may include the package substrate 100, the pair of first semiconductor chips 110R and 110L, the pair of second semiconductor chips 120R and 120L, a molding member MB20, and the encapsulation EC.

In the semiconductor package 2 of the some example embodiments, the underfill UF (see FIG. 1) may be omitted, and the molding member MB20 may be formed by using a molded underfill (MUF) process. Accordingly, the gap between the pair of first semiconductor chips 110R and 110L and the pair of second semiconductor chips 120R and 120L may be filled by the molding member MB20.

The molding member MB20 may be formed by injecting a proper amount of molding material onto the package substrate 100 by an injection process and performing a hardening process thereon. When beneficial, in a pressure process such as a press process, pressure may be applied to the molding material.

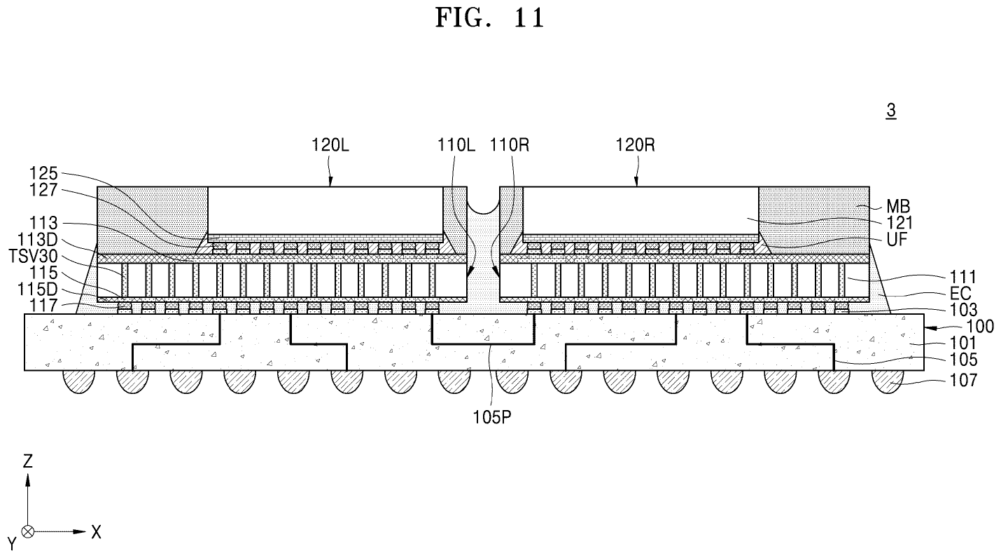

Referring to FIG. 11, a semiconductor package 3 may include the package substrate 100, the pair of first semiconductor chips 110R and 110L including a plurality of through silicon vias TSV30, the pair of second semiconductor chips 120R and 120L, the underfill UF, the molding member MB, and the encapsulation EC.

In the semiconductor package 3 of the some example embodiments, each of the pair of first semiconductor chips 110R and 110L may include the plurality of through silicon vias TSV30 passing through the base substrate 111. The plurality of through silicon vias TSV30 may be arranged both in the region where the left first semiconductor chip 110L and the left second semiconductor chip 120L overlap each other in the vertical direction (Z direction) and in the region where the left first semiconductor chip 110L and the left second semiconductor chip 120L do not overlap each other in the vertical direction (Z direction). In addition, the plurality of through silicon vias TSV30 may be arranged both in the region where the right first semiconductor chip 110R and the right second semiconductor chip 120R overlap each other in the vertical direction (Z direction) and in the region where the right first semiconductor chip 110R and the right second semiconductor chip 120R do not overlap each other in the vertical direction (Z direction).

In the region where the pair of first semiconductor chips 110R and 110L and the pair of second semiconductor chips 120R and 120L overlap each other in the vertical direction (Z direction), the plurality of through silicon vias TSV30 may transmit electrical signals.

Unlike the above, in the region where the pair of first semiconductor chips 110R and 110L and the pair of second semiconductor chips 120R and 120L do not overlap each other in the vertical direction (Z direction), the plurality of through silicon vias TSV30 may increase a degree of physical coupling and/or transmit heat.

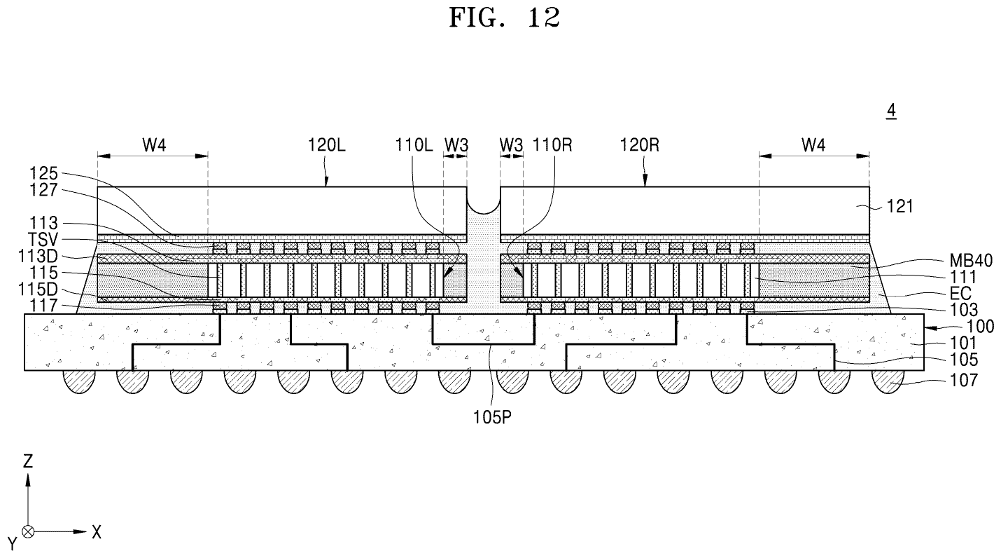

Referring to FIG. 12, a semiconductor package 4 may include the package substrate 100, the pair of first semiconductor chips 110R and 110L, the pair of second semiconductor chips 120R and 120L, a molding member MB40, and the encapsulation EC.

In the semiconductor package 4 of the some example embodiments, the width of each of the pair of second semiconductor chips 120R and 120L in the first horizontal direction (X direction) may be greater than the width of each of the pair of first semiconductor chips 110R and 110L in the first horizontal direction (X direction).

The molding member MB40 may be formed to surround the lateral surface of each of the pair of first semiconductor chips 110R and 110L. The molding member MB40 may function as an extension region for the upper redistribution layer 113 and the lower redistribution layer 115 of each of the pair of first semiconductor chips 110R and 110L.

In the semiconductor package 4 of the some example embodiments, as for the width of the molding member MB40 in the first horizontal direction (X direction), a third width W3 in a region where the pair of first semiconductor chips 110R and 110L face each other may be less than a fourth width W4 in a region where the pair of first semiconductor chips 110R and 110L do not face each other.

The semiconductor package 4 of the some example embodiments may include, on the package substrate 100, the encapsulation EC covering the periphery of the molding member MB40 and a part of the pair of second semiconductor chips 120R and 120L.

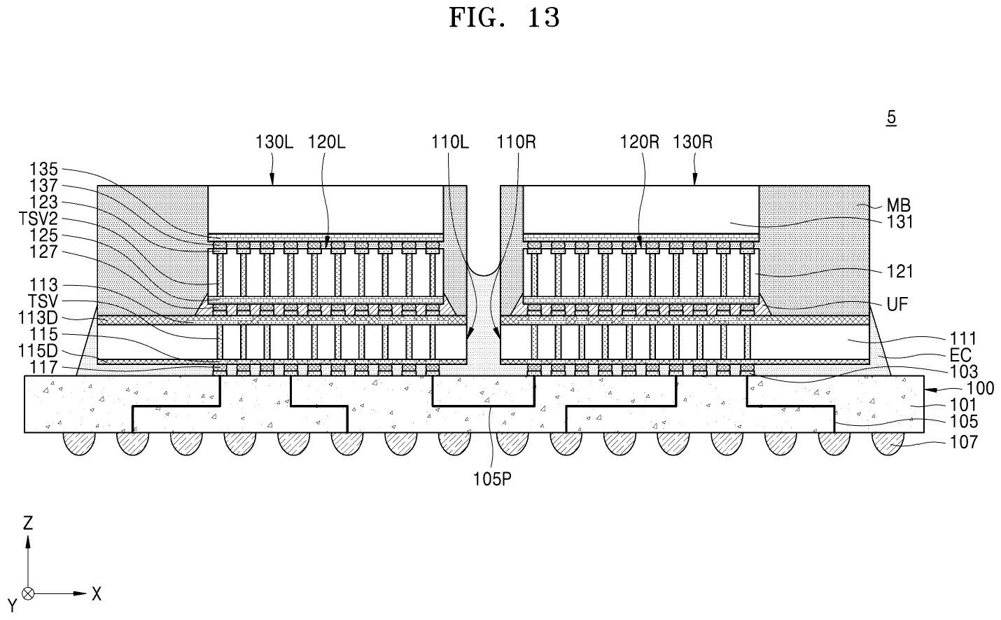

Referring to FIG. 13, a semiconductor package 5 may include the package substrate 100, the pair of first semiconductor chips 110R and 110L, the pair of second semiconductor chips 120R and 120L, a pair of third semiconductor chips 130R and 130L, the underfill UF, the molding member MB, and the encapsulation EC.

In the semiconductor package 5 of the some example embodiments, the pair of third semiconductor chips 130R and 130L may be mounted on the pair of second semiconductor chips 120R and 120L.

The pair of third semiconductor chips 130R and 130L may respectively be referred to as the left third semiconductor chip 130L and the right third semiconductor chip 130R according to their positions in the drawings. That is, the left third semiconductor chip 130L may be mounted on the left second semiconductor chip 120L, and the right third semiconductor chip 130R may be mounted on the right second semiconductor chip 120R.

In some example embodiments, each of the pair of third semiconductor chips 130R and 130L may be a memory chip, and may include, for example, a volatile memory chip and/or a non-volatile memory chip. The pair of third semiconductor chips 130R and 130L may include a memory chip set capable of mutual data aggregation and data aggregation with the pair of second semiconductor chips 120R and 120L. For example, the pair of third semiconductor chips 130R and 130L and the pair of second semiconductor chips 120R and 120L may be high bandwidth memory (HBM).

In addition, the width of each of the third semiconductor chips 130R and 130L in the first horizontal direction (X direction) may be identical or substantially identical to the width of each of the second semiconductor chips 120R and 120L in the first horizontal direction (X direction).

Each of the pair of third semiconductor chips 130R and 130L may include a base substrate 131 and a lower wiring layer 135 formed on a lower surface of the base substrate 131. The base substrate 131 may be a wafer including silicon (Si), for example, crystalline silicon, polycrystalline silicon, or amorphous silicon.

The pair of third semiconductor chips 130R and 130L may be electrically connected to the pair of second semiconductor chips 120R and 120L through a third internal connection terminal 137 located under the lower wiring layer 135. Each of the pair of second semiconductor chips 120R and 120L may include an upper wiring layer 123 formed on the upper surface of the base substrate 121 and a plurality of through silicon vias TSV2 passing through the base substrate 121.

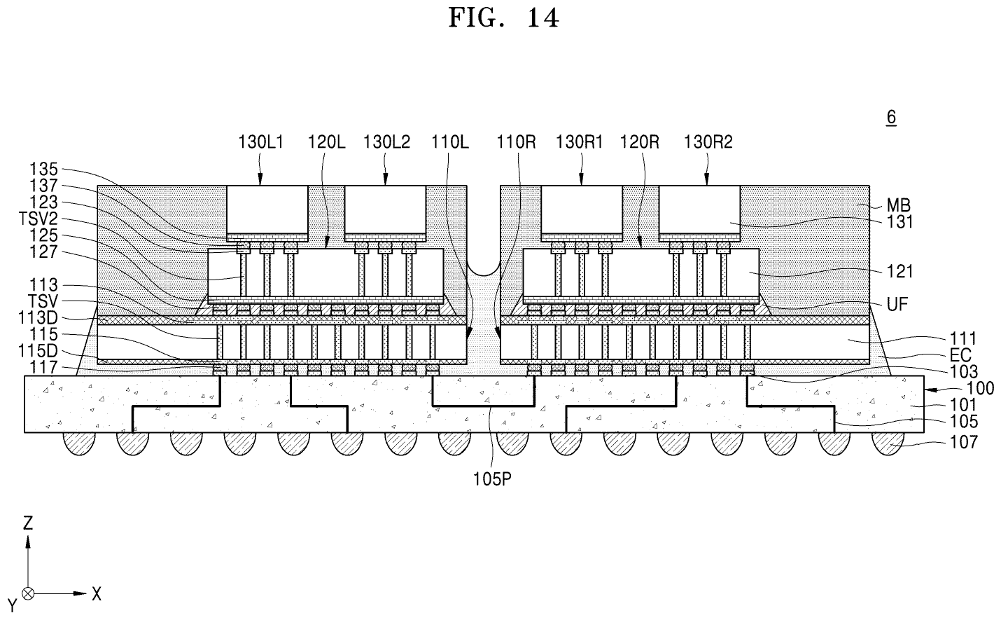

Referring to FIG. 14, a semiconductor package 6 may include the package substrate 100, the pair of first semiconductor chips 110R and 110L, the pair of second semiconductor chips 120R and 120L, four third semiconductor chips 130R1, 130R2, 130L1, and 130L2, the underfill UF, the molding member MB, and the encapsulation EC.

In the semiconductor package 6 of the some example embodiments, a pair of left third semiconductor chips 130L1 and 130L2 may be mounted on the left second semiconductor chip 120L, and a pair of right third semiconductor chips 130R1 and 130R2 may be mounted on the right second semiconductor chip 120R.

In addition, the width of each of the four third semiconductor chips 130R1, 130R2, 130L1, and 130L2 in the first horizontal direction (X direction) may be less than the width of each of the second semiconductor chips 120R and 120L in the first horizontal direction (X direction).

Each of the four third semiconductor chips 130R1, 130R2, 130L1, and 130L2 may include the base substrate 131 and the lower wiring layer 135 formed on the lower surface of the base substrate 131. The base substrate 131 may be a wafer including silicon (Si), for example, crystalline silicon, polycrystalline silicon, or amorphous silicon.

The four third semiconductor chips 130R1, 130R2, 130L1, and 130L2 may be electrically connected to the pair of second semiconductor chips 120R and 120L through the third internal connection terminal 137 located under the lower wiring layer 135. Each of the pair of second semiconductor chips 120R and 120L may include the upper wiring layer 123 formed on the upper surface of the base substrate 121 and the plurality of through silicon vias TSV2 passing through the base substrate 121.

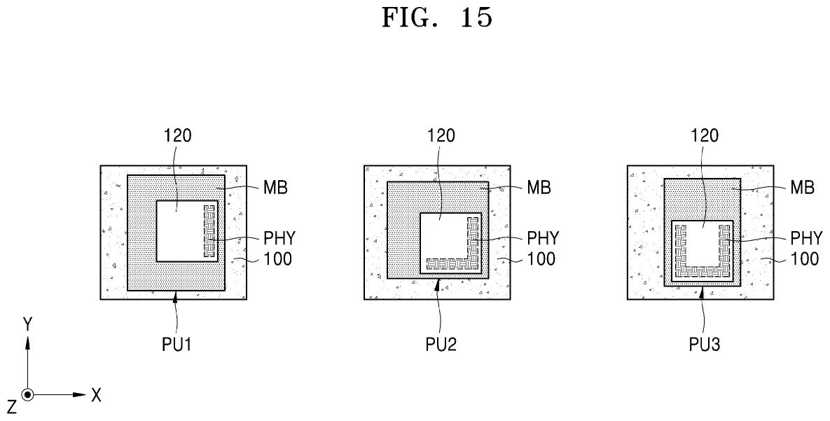

FIGS. 15 to 19 are plan views illustrating major components of a semiconductor package according to some example embodiments.

FIG. 15 illustrates first to third package units PU1, PU2, and PU3 each including a second semiconductor chip 120 in which the molding member MB is asymmetrically arranged with respect to each side of the second semiconductor chip 120.

The second semiconductor chip 120 may refer to any one of the pair of second semiconductor chips 120R and 120L. The second semiconductor chip 120 may include a physical signal connection structure PHY. The physical signal connection structure PHY may be a part of the lower wiring layer 125 described above and may refer to a structure which receives and transmits signals between neighboring second semiconductor chips 120.

The minimum distance from the four sides of the second semiconductor chip 120 in the first horizontal direction (X direction) and the second horizontal direction (Y direction) to the corresponding four sides of the molding member MB may be different in one side. That is, the molding member MB may be arranged asymmetrically with respect to the four sides of the second semiconductor chip 120. In addition, the physical signal connection structure PHY may be arranged in a region where the minimum distance from the four sides of the second semiconductor chip 120 to the corresponding four sides of the molding member MB is reduced.

Each of the first to third package units PU1, PU2, and PU3 may include the first semiconductor chip (any one of 110R and 110L, see FIG. 1), the second semiconductor chip 120, the underfill UF (see FIG. 1), the molding member MB, and the encapsulation EC (see FIG. 1). In addition, each of the first to third package units PU1, PU2, and PU3 may be mounted on the package substrate 100. In this regard, for convenience, some example embodiments are described by focusing on the arrangement of the second semiconductor chip 120 and the molding member MB.

In the first package unit PU1, the width of the molding member MB, which is in contact with the right side of the second semiconductor chip 120, may be relatively less than the width of the molding member MB, which is in contact with other sides (upper side, lower side, and left side) of the second semiconductor chip 120. Accordingly, in the first package unit PU1, the physical signal connection structure PHY may be inclined to the right side of the second semiconductor chip 120.

In the second package unit PU2, the width of the molding member MB, which is in contact with the lower side and the right side of the second semiconductor chip 120 may be relatively less than the width of the molding member MB, which is in contact with other sides (upper side and left side) of the second semiconductor chip 120. Accordingly, in the third package unit PU3, the physical signal connection structure PHY may be inclined to the lower side and the right side of the second semiconductor chip 120.

In the third package unit PU3, the width of the molding member MB, which is in contact with the lower side, the left side, and the right side of the second semiconductor chip 120 may be relatively less than the width of the molding member MB, which is in contact with other side (upper side) of the second semiconductor chip 120. Accordingly, in the first package unit PU1, the physical signal connection structure PHY may be inclined to the lower side, left side, and the right side of the second semiconductor chip 120.

Referring to FIG. 16, in a semiconductor package 10, a pair of first package units PU1 facing each other may be mounted on the package substrate 100.

The semiconductor package 10 of the some example embodiments may be identical or substantially identical to the semiconductor package 1 (see FIG. 2). That is, the pair of first package units PU1 may be arranged on the package substrate 100 in such a manner that a distance between the physical signal connection structures PHY becomes shortest.

In the semiconductor package 10 of the some example embodiments, by reducing the distance between the physical signal connection structures PHY receiving and transmitting signals between the second semiconductor chip 120 located on the right side and the second semiconductor chip 120 located on the left side, the connection distance of wires for signal connection may be reduced.

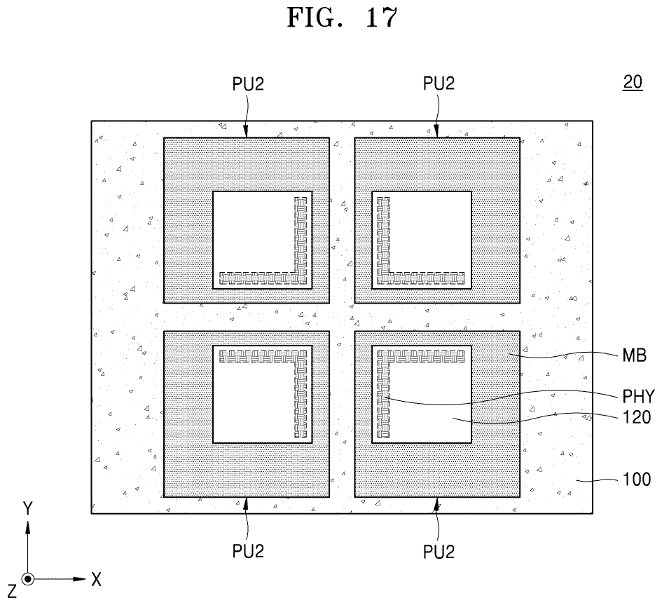

Referring to FIG. 17, in a semiconductor package 20, four second package units PU2 facing each other may be mounted on the package substrate 100.

In the semiconductor package 20 of the some example embodiments, four second package units PU2 may be mounted on the package substrate 100 in such a manner that a distance between the physical signal connection structures PHY becomes shortest.

In the semiconductor package 20 of the some example embodiments, by reducing the distance between the physical signal connection structures PHY receiving and transmitting signals among the four second package units PU2, the connection distance of wires for signal connection may be reduced.

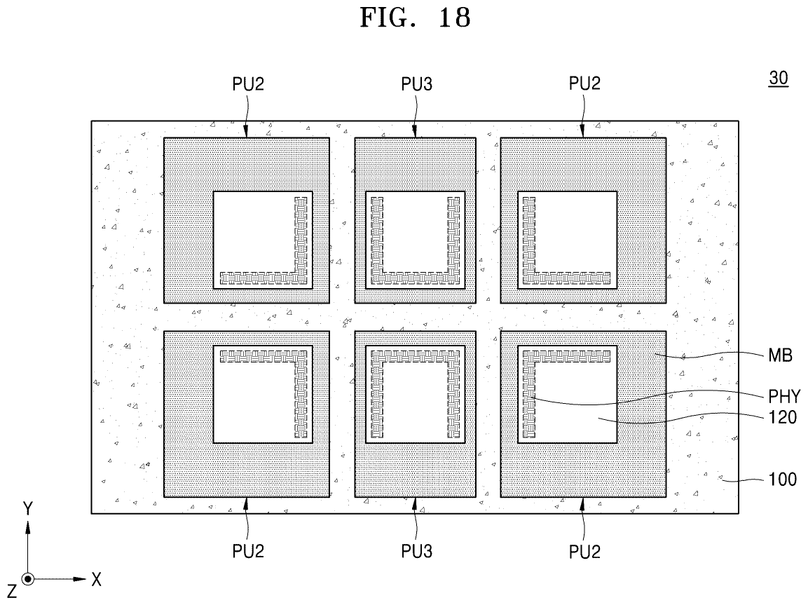

Referring to FIG. 18, in a semiconductor package 30, four second package units PU2 and two third package units PU3, which face each other, may be mounted on the package substrate 100.

In the semiconductor package 30 of the some example embodiments, four second package units PU2 may be arranged and mounted on the package substrate 100 in a mirror-image symmetrical structure with two third package units PU3 located therebetween such that a distance between the physical signal connection structures PHY becomes shortest.

In the semiconductor package 30 of the some example embodiments, by reducing the distance between the physical signal connection structures PHY receiving and transmitting signals between the four second package units PU2 and the two third package units PU3, the connection distance of wires for signal connection may be reduced.

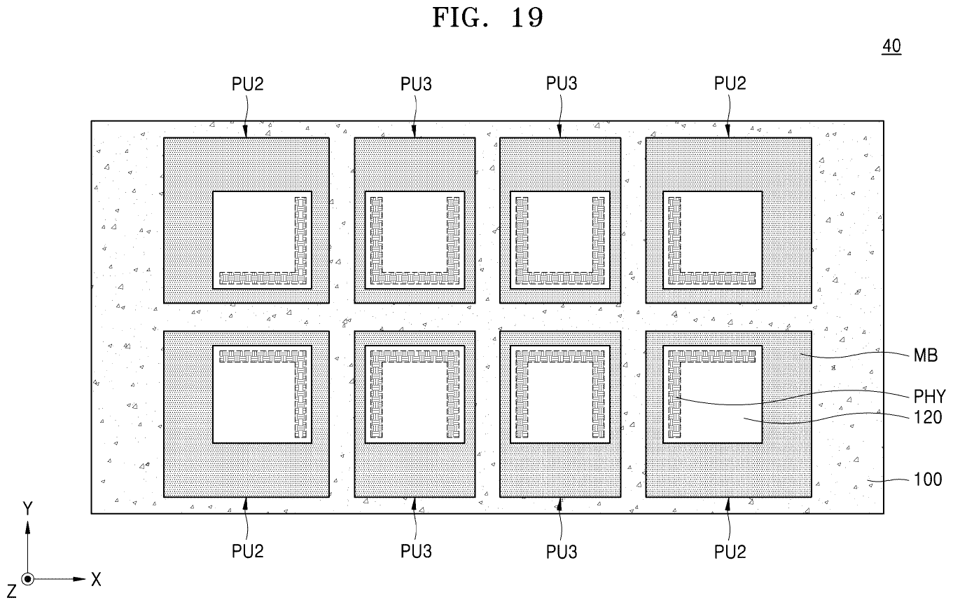

Referring to FIG. 19, in a semiconductor package 40, four second package units PU2 and four third package units PU3, which face each other, may be mounted on the package substrate 100.

In the semiconductor package 40 of the some example embodiments, four second package units PU2 may be arranged and mounted on the package substrate 100 in a mirror-image symmetrical structure with four third package units PU3 located therebetween such that a distance between the physical signal connection structures PHY becomes shortest.

In the semiconductor package 40 of the some example embodiments, by reducing the distance between the physical signal connection structures PHY receiving and transmitting signals between the four second package units PU2 and the four third package units PU3, the connection distance of wires for signal connection may be reduced.

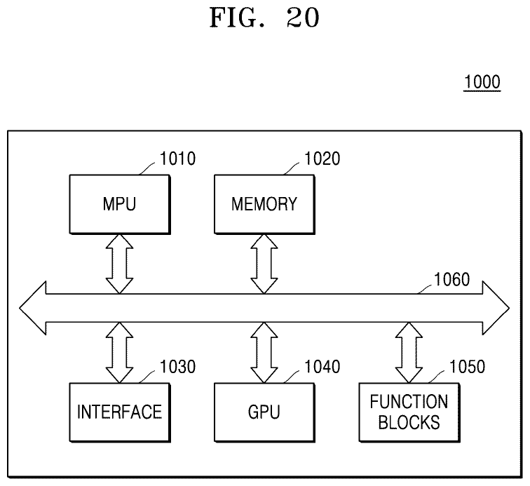

FIG. 20 is a block diagram schematically illustrating configuration of a semiconductor package according to some example embodiments.

Referring to FIG. 20, a semiconductor package 1000 may include a micro processing unit (MPU) 1010, a memory 1020, an interface 1030, a graphics processing unit (GPU) 1040, function blocks 1050, and a bus 1060 connecting these components.

The semiconductor package 1000 may include both of the MPU 1010 and the GPU 1040 or may include one of them.

The MPU 1010 may include a core and a cache. For example, the MPU 1010 may include multiple cores. The performance of the multiple cores may be the same or different. In addition, the multiple cores may be activated at the same time or at different times from each other.

The memory 1020 may store results, etc. processed from the function blocks 1050 according to the control by the MPU 1010. The interface 1030 may receive or transmit information or signals with external devices. The GPU 1040 may perform graphic functions. For example, the GPU 1040 may perform a video codec or may process three-dimensional (3D) graphics. The function blocks 1050 may perform various functions. For example, when the semiconductor package 1000 is an application processor used in a mobile device, some of the function blocks 1050 may perform the communication function.

The semiconductor package 1000 may include any one of the semiconductor packages 1, 2, 3, 4, 5, 6, 10, 20, 30, and/or 40 described above.

When the terms “about” or “substantially” are used in this specification in connection with a numerical value, it is intended that the associated numerical value includes a manufacturing or operational tolerance (e.g., ±10 %) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10 %) around the stated numerical values or shapes.

As described herein, any electronic devices and/or portions thereof according to any of the example embodiments may include, may be included in, and/or may be implemented by one or more instances of processing circuitry such as hardware including logic circuits; a hardware/software combination such as a processor executing software; or any combination thereof. For example, the processing circuitry more specifically may include, but is not limited to, a central processing unit (CPU), an arithmetic logic unit (ALU), a graphics processing unit (GPU), an application processor (AP), a digital signal processor (DSP), a microcomputer, a field programmable gate array (FPGA), and programmable logic unit, a microprocessor, application-specific integrated circuit (ASIC), a neural network processing unit (NPU), an Electronic Control Unit (ECU), an Image Signal Processor (ISP), and the like. In some example embodiments, the processing circuitry may include a non-transitory computer readable storage device (e.g., a memory), for example a DRAM device, storing a program of instructions, and a processor (e.g., CPU) configured to execute the program of instructions to implement the functionality and/or methods performed by some or all of any devices, systems, modules, units, controllers, circuits, architectures, and/or portions thereof according to any of the example embodiments, and/or any portions thereof.

While the inventive concepts have been particularly shown and described with reference to example embodiments thereof, it will be understood that various changes in form and details may be made therein without departing from the spirit and scope of the following claims.

What is claimed is:

1. A semiconductor package comprising:
a package substrate;
a pair of first semiconductor chips on the package substrate and facing each other in a horizontal direction;
a pair of second semiconductor chips on the pair of first semiconductor chips and facing each other in the horizontal direction;
a pair of molding members covering a periphery of the pair of second semiconductor chips on the pair of first semiconductor chips; and
an encapsulation covering a periphery of the pair of first semiconductor chips and a part of the pair of molding members on the package substrate,
each of the pair of molding members include first and second widths in the horizontal direction, the first width in a first region where the pair of second semiconductor chips face each other is less than the second width in a second region where the pair of second semiconductor chips do not face each other, and
a first upper surface of the encapsulation in the first region is higher than a second upper surface of the encapsulation in the second region.

2. The semiconductor package of claim 1, wherein
a sidewall of each of the pair of first semiconductor chips is coplanar with a sidewall of each of the pair of molding members in a vertical direction, and
the encapsulation has a round upper surface in the first region and an inclined sidewall in the second region.

3. The semiconductor package of claim 2, wherein
a vertical level of an uppermost surface of the pair of molding members is identical to a vertical level of an uppermost surface of the pair of second semiconductor chips, and
the vertical level of the uppermost surface of the pair of molding members is higher than the vertical level of the uppermost surface of the encapsulation.

4. The semiconductor package of claim 1, wherein a width of each of the pair of second semiconductor chips in the horizontal direction is less than a width of each of the pair of first semiconductor chips in the horizontal direction.

5. The semiconductor package of claim 4, wherein
each of the pair of first semiconductor chips includes a plurality of through electrodes, and
the plurality of through electrodes are only in a region which overlaps the pair of second semiconductor chips in a vertical direction.

6. The semiconductor package of claim 4, wherein
each of the pair of first semiconductor chips includes a plurality of through electrodes, and
the plurality of through electrodes are both in a region which overlaps the pair of second semiconductor chips in a vertical direction and in a region which does not overlap the pair of second semiconductor chips in the vertical direction.

7. The semiconductor package of claim 1, wherein a pair of physical signal connection structures configured to receive and transmit signals between the pair of second semiconductor chips are adjacent to the first region.

8. The semiconductor package of claim 7, wherein the pair of physical signal connection structures are electrically connected to each other through the pair of first semiconductor chips and the package substrate.

9. The semiconductor package of claim 1, further comprising:
a plurality of bump structures between the pair of first semiconductor chips and the pair of second semiconductor chips and electrically connecting the pair of first semiconductor chips with the pair of second semiconductor chips; and
a pair of underfills surrounding the plurality of bump structures.

10. The semiconductor package of claim 9, wherein
the pair of molding members surround the pair of underfills, and
the pair of underfills are not in contact with the encapsulation.

11. A semiconductor package comprising:
a package substrate;
a pair of first semiconductor chips on the package substrate and facing each other in a horizontal direction;
a pair of second semiconductor chips on the pair of first semiconductor chips and facing each other in the horizontal direction;
a pair of molding members covering a periphery of the pair of first semiconductor chips; and
an encapsulation covering a periphery of the pair of molding members and a part of the pair of second semiconductor chips on the package substrate,
each of the pair of molding members include first and second widths in the horizontal direction, the first width in a first region where the pair of first semiconductor chips face each other is less than the second width in a second region where the pair of first semiconductor chips do not face each other, and
a first upper surface of the encapsulation in the first region is higher than a second upper surface of the encapsulation in the second region.

12. The semiconductor package of claim 11, wherein a width of each of the pair of first semiconductor chips in the horizontal direction is less than a width of each of the pair of second semiconductor chips in the horizontal direction.

13. The semiconductor package of claim 12, wherein
a sidewall of each of the pair of second semiconductor chips is coplanar with a sidewall of each of the pair of molding members in a vertical direction, and
the encapsulation has a round upper surface in the first region and an inclined sidewall in the second region.

14. The semiconductor package of claim 11, wherein a pair of physical signal connection structures configured to receive and transmit signals between the pair of second semiconductor chips are adjacent to the first region.

15. The semiconductor package of claim 14, wherein
the package substrate includes a wiring layer therein,
each of the pair of first semiconductor chips includes a plurality of through electrodes, and
the pair of physical signal connection structures are electrically connected to each other through the pair of through electrodes and the wiring layer.

16. A semiconductor package comprising:
a package substrate;
a plurality of first semiconductor chips on the package substrate and facing each other in a horizontal direction;
a plurality of second semiconductor chips on the plurality of first semiconductor chips and facing each other in the horizontal direction;
a plurality of third semiconductor chips on the plurality of second semiconductor chips and facing each other in the horizontal direction;
a plurality of molding members covering peripheries of the plurality of second semiconductor chips and the plurality of third semiconductor chips on the plurality of first semiconductor chips; and
an encapsulation covering a periphery of the plurality of first semiconductor chips and a part of the plurality of molding members on the package substrate,
each of the plurality of molding members includes first and second widths in the horizontal direction, the first width in a first region where the plurality of second semiconductor chips face each other is less than the second width in a second region where the plurality of second semiconductor chips do not face each other, and
a first upper surface of the encapsulation in the first region is higher than a second upper surface of the encapsulation in the second region.

17. The semiconductor package of claim 16, wherein
a width of each of the plurality of second semiconductor chips in the horizontal direction is identical to a width of each of the plurality of third semiconductor chips in the horizontal direction, and
the width of each of the plurality of second semiconductor chips in the horizontal direction is less than a width of each of the plurality of first semiconductor chips in the horizontal direction.

18. The semiconductor package of claim 16, wherein
the plurality of third semiconductor chips are on each of the plurality of second semiconductor chips,
a width of each of the plurality of second semiconductor chips in the horizontal direction is greater than a width of each of the plurality of third semiconductor chips in the horizontal direction, and
the width of each of the plurality of second semiconductor chips in the horizontal direction is less than a width of each of the plurality of first semiconductor chips in the horizontal direction.

19. The semiconductor package of claim 16, wherein each of the plurality of first and second semiconductor chips includes a plurality of through electrodes.

20. The semiconductor package of claim 19, wherein
each of the plurality of first semiconductor chips comprises an interposer,
each of the plurality of second and third semiconductor chips includes an active device, and
the plurality of first semiconductor chips, the plurality of second semiconductor chips, and the plurality of third semiconductor chips comprise a system-in-package in which the plurality of first to third semiconductor chips are electrically connected to each other.
